(19) United States
(12) Patent Application Publication
(10) Pub. No.: US 2009/0079487 A1
(43) Pub. Date: Mar. 26, 2009

(54) Time Delay Line with Low Sensitivity to Process Variations

(75) Inventors: Torkel Arnborg, Stockholm (SE); Roland Strandberg, Malmo (SE)

Correspondence Address: COATS & BENNETT, PLLC, 1400 Crescent Green, Suite 300, Cary, NC, 27518, US

(73) Assignee: Telefonaktiebolaget LM Ericsson (publ), Stockholm (SE)

(21) Appl. No.: 11/861,353

(22) Filed: Sep. 26, 2007

(51) Int. Cl. H03H 11/26

(52) U.S. Cl. 327/285

(57) ABSTRACT

A time delay line comprises a plurality of delay elements connected in series. Each delay element comprises one or more transistors that exhibit a reverse short channel effect at channel lengths within a certain range. The transistors are configured to have a channel length in the certain range in order to reduce time delay sensitivity to process variations.

### BACKGROUND

The present invention relates generally to methods of reducing sensitivity of delay elements to process variations, and to delay elements with reduced sensitivity to process variations.

Delay elements are commonly used in mixed signal circuits to compensate for timing delays, or to actively control timing or frequency behavior of the circuits. For example, delay elements are commonly found in frequency synthesizers and delta-sigma analog-to-digital converters. There are many ways to construct a delay element. For example, delay elements can be constructed with RC networks, inverters, diodes, transistors, transmission lines, or a combination thereof.

Delay lines comprising a plurality of inverters connected in series are commonly used as delay elements because they are easy to implement in integrated circuits and can be used with mixed signal circuits to preserve the magnitude and shape of the voltage waveform. Due to process variations that occur during manufacturing, the actual delay produced by a delay line may vary slightly from a nominal or expected delay. For many applications, the deviation from the nominal delay will not be significant. However, there will be many instances where the delay line is expected to meet strict manufacturing requirements to be useful in large volume integrated circuits. Therefore, there is interest in finding new ways to reduce the delay spread in time delay lines to improve accuracy and increase production yields.

### SUMMARY

The present invention provides a method of reducing the sensitivity of a time delay line to process variations. The delay line comprises a plurality of delay elements. Each delay element is formed from one or more transistors that exhibit a reverse short channel effect for channel lengths within a certain range, referred to as the RSCE range. The delay time sensitivity to process variation is reduced by configuring the transistors to have a channel length in the RSCE range. The reduction in delay time sensitivity results in increased yields and lower manufacturing costs.

### BRIEF DESCRIPTION OF THE DRAWINGS

FIG. 1 illustrates an exemplary delay line comprising a plurality of inverters according to one embodiment of the present invention.

FIG. 2 illustrates an exemplary inverter for the delay line in FIG. 1.

FIG. 3 illustrates the relationship between threshold voltage and channel length for transistors made using a process without RSCE and a process with RSCE.

FIG. 4 illustrates the relationship between threshold voltage and channel length for transistors used in an exemplary delay line as shown in FIG. 1.

FIG. 5 illustrates the relationship between mean delay and channel length for an exemplary delay line as shown in FIG. 1.

FIG. 6 illustrates an exemplary phase locked loop (PLL).

FIG. 7 illustrates the relationship between output current and phase error for a conventional PLL without a delay line.

FIG. 8 illustrates the relationship between output current and phase error for a PLL with a delay line.

FIG. 9 illustrates an exemplary phase detector with a delay line.

FIG. 10 is a schematic block diagram of an amplifier circuit.

FIG. 11 illustrates an exemplary delay locked loop.

### DETAILED DESCRIPTION

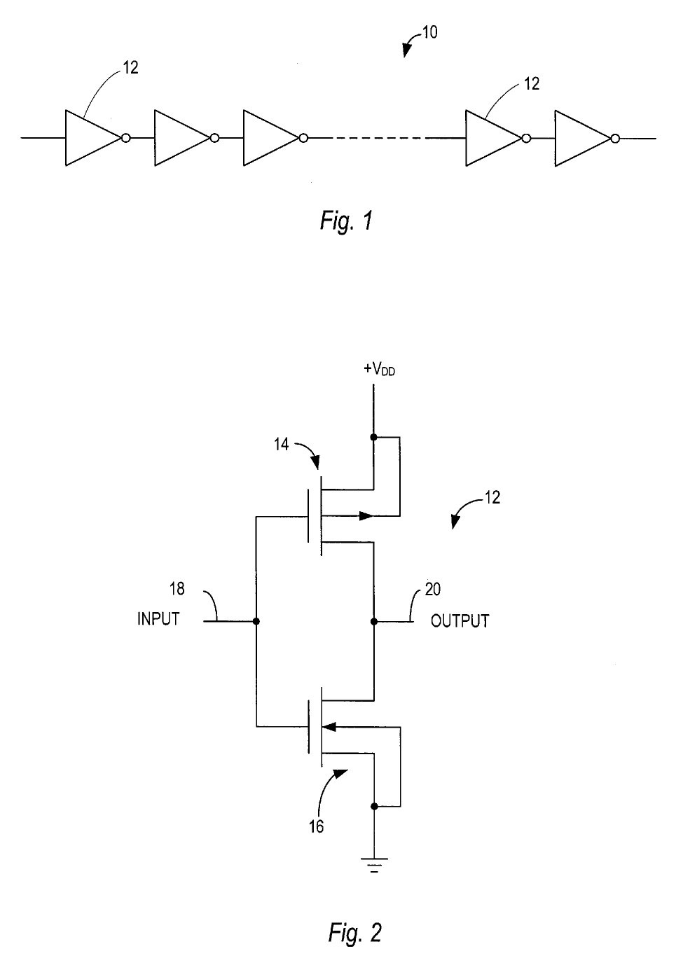

FIG. 1 illustrates a delay line 10 according to one exemplary embodiment. The delay line 10 comprises a plurality of delay elements 12 connected in series. In the exemplary embodiment, the delay elements 12 comprise a series of inverters. Those skilled in the art will appreciate that other types of delay elements could also be used. Each inverter 12 is designed to produce a nominal delay. The total delay of delay line 10 is the sum of the delays produced by all of the inverters 12. Process variations during manufacturing may cause the actual delay of the inverters 12 to deviate from the nominal delay. The range of the variation from the nominal delay is referred to as delay spread. The present invention reduces the delay spread by reducing the sensitivity of the delay line 10 to process variations.

FIG. 2 illustrates an exemplary inverter 12. Inverter 12 comprises a pair of complementary metal oxide semiconductor (CMOS) transistors 14, 16 connected in series and configured to be alternately enabled. Transistor 14 is a p-type transistor, while transistor 16 is an n-type transistor. The input 18 of inverter 12 connects to the gates of both transistors 14, 16. A voltage source (not shown) connects to the source of transistor 14. The source of transistor 16 connects to ground. The drain of both transistors 14, 16 connects to the output 20 of the inverter 12.

When the input 18 to the inverter 12 is high, transistor 14 is switched off and transistor 16 is switched on. Current flows from the output 20 of the inverter 12 to ground. Conversely, when the input 18 to the inverter 12 is low, transistor 14 is switched on and transistor 16 is switched off. In this case, current flows from the voltage source to the output 20 of the inverter 12.

When a signal is applied to the input 18 of the inverter 12, there will be a small delay before the signal appears at the output 20 of the inverter 12. The amount of this delay is a function of the channel length of the transistors 14, 16. In general, a short channel length produces a short delay and a long channel length produces a long delay. Process variations during manufacturing may cause the actual delay of the inverters 12 to deviate from the nominal delay. The main geometrical process variations that contribute to delay spread are channel length, channel width, and oxide thickness. Of these three, the channel length is the most critical. The channel width is less important because the channel width tends to be large in comparison to the process variation. The gate capacitance, which depends on the oxide thickness, is less critical because the drive current and load capacitance vary in opposite directions.

One model of the delay tₚ in inverter 12 is given by:

$${t}_{p} ∝ \frac{{V}_{DD} {C}_{GATE}}{{{K}_{n} ( {V}_{DD} - {V}_{Tn} )}^{2} + {{K}_{p} ( {V}_{DD} - {V}_{Tp} )}^{2}} \qquad Eq . ( 1 )$$

where V_{DD} is the supply voltage at the source of transistor 14, V_{Tp} is the threshold voltage of the p-type transistor 14, V_{Tn} is the threshold voltage of the n-type transistor 16, Kₚ is the gain factor of the p-type transistor 14, Kₙ is the gain factor of the n-type transistor 16, and C_{GATE} is the gate capacitance of the inverter 12.

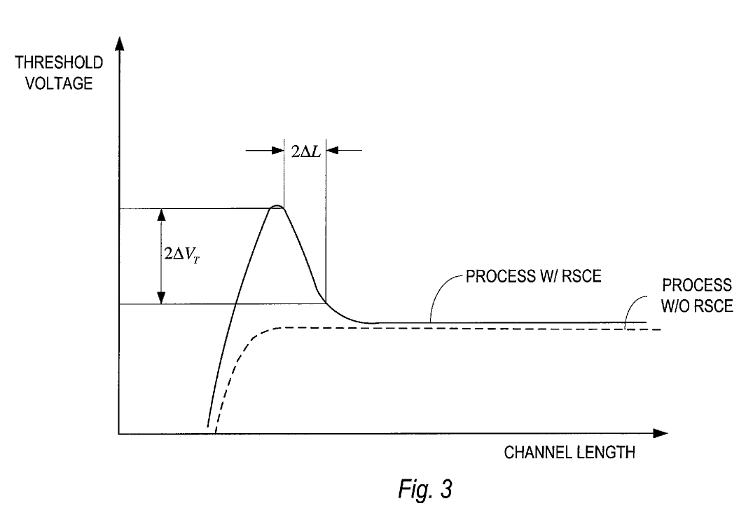

The threshold voltages V_{Tp} and V_{Tn} are a strong function of the channel length of the transistors 14, 16. FIG. 3 illustrates the relationship between threshold voltage and channel length for transistors 14, 16 manufactured using a conventional process without reverse short channel effect and a process with RSCE. As seen in FIG. 3, the threshold voltage is almost constant for long channel lengths. For short channel lengths, the threshold voltage drops in transistors manufactured with processes without the RSCE. For transistors manufactured using processes with RSCE, the threshold voltage initially increases as the channel length is made shorter before it decreases. Within the RSCE range of the threshold voltage curve, the threshold voltage decreases with increasing channel length.

In the past, the variation in threshold voltage has been considered a disadvantage. Therefore, circuit designers have conventionally avoided designs in which the channel lengths of the transistors 14, 16 fall within the RSCE range. In contrast to the conventional wisdom, the present invention exploits the RSCE to reduce the sensitivity of the delay in the inverters 12 to process variations during manufacturing.

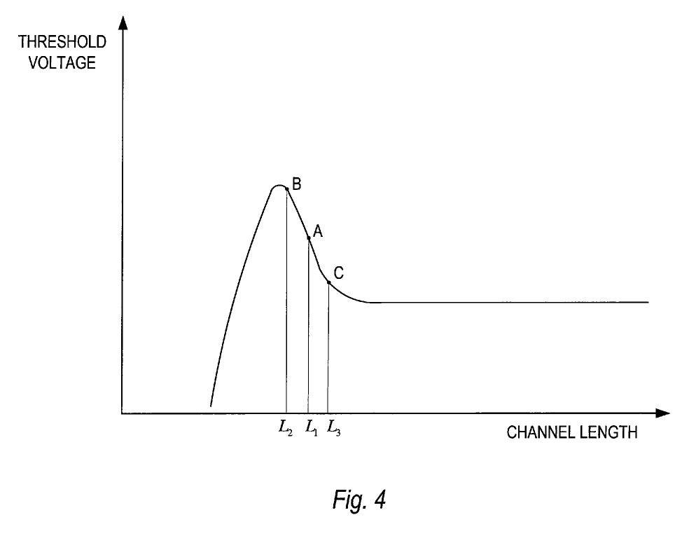

According to one exemplary embodiment, a delay line 10 as shown in FIG. 1 is formed of transistors 14, 16 that exhibit an RSCE at channel lengths within a certain range, referred to herein as the RSCE range. FIG. 4 illustrates an exemplary threshold voltage curve for the transistors 14, 16. The RSCE range of the threshold voltage curve extends from point B to point C with a midpoint A. The designed channel length Lₜ of the transistors 12 is selected to fall near a midpoint A of the RSCE range of the threshold voltage curve. Process variations will cause the actual channel length to vary around point A between a minimum channel length L₂ and a maximum channel length L₃, corresponding to points B and C respectively on the threshold voltage curve. Those skilled in the art may appreciate that the channel length L₁ may be different for the n-type and p-type transistors. Also, while the minimum channel length L₁ and maximum channel length L₃ are shown as falling inside the RSCE range, these points may also fall outside of the RSCE range of the curve. The designed channel length L₁, however, should fall within the RSCE range, even if in rare cases the channel length of a transistor falls outside the RSCE range due to process variations.

By configuring the desired channel length to lie within the RSCE range of the threshold voltage curve, the sensitivity of the delay in the transistors 14, 16 to process variations is significantly reduced. Within the RSCE range of the threshold voltage curve, the threshold voltage increases with decreasing channel length and vice versa. As the channel length is reduced, the squared gate overdrive voltages (V_{DD}−V_{Tn})² and (V_{DD}−V_{Tp})² in Eq. 1 decrease. On the other hand, the channel gain factors Kₚ and Kₙ are inversely proportional to the channel length. When the channel length decreases, the gain factors Kₚ and Kₙ increase. The net result of these variations is to reduce the sensitivity of the delay to variation in the channel lengths because the squared gate overdrive voltages and the gain factors always move in opposite directions. Without the RSCE, the gate overdrive voltages and the gain factors would move together in the same direction to cause significant variation in the delay.

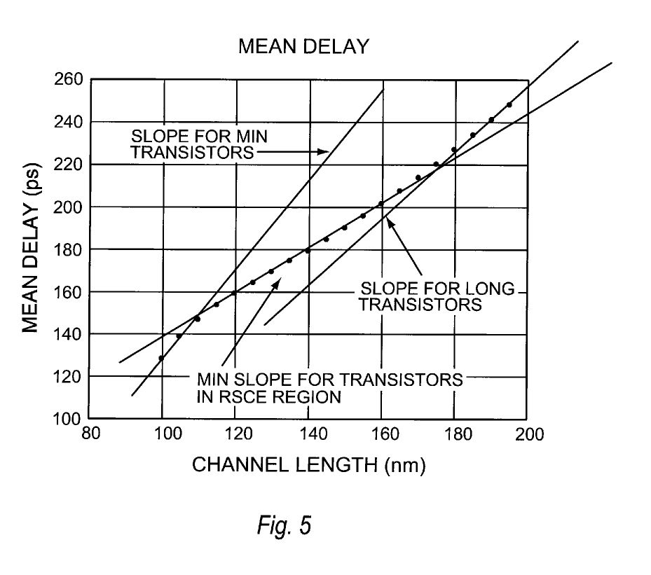

FIG. 5 illustrates the relationship between mean delay and channel length in a 12-transistor delay line 10 for an exemplary process with RSCE. As seen in FIG. 5, the mean delay is increasing with increasing channel length. The slope of the curve represents the sensitivity of the delay to process variations. A lower slope indicates lower delay time sensitivity to process variation. It may be noted that the curve can be approximated with three lines of different slopes. At channel lengths below the minimum channel length L₂, the slope of the curve is large. For channel lengths within the RSCE range, the slope is lower. For channel lengths greater than the maximum channel length L₃, the slope is once again large. Thus, by staying within the RSCE range, sensitivity to process variation is significantly reduced.

For a typical 90 nm process in use today, the RSCE range is about 110 nm to about 180 nm. The midpoint is around 140 nm. According to the present invention, the channel length of the transistor 14, 16 may be selected to be close to 140 nm. The RSCE range will, of course, vary for different processes and this example is provided only for illustration. As transistors decrease in size, the RSCE phenomenon is expected remain or become more pronounced. In this case, the yield and performance increases realized from the present invention will become greater.

A delay line 10 as described herein may be implemented with low circuit complexity while achieving high yield due to lower sensitivity to process variations. The RSCE will continue to be a problem for transistors made with channel lengths below 100 nanometers because no breakthrough in process technology has been made to date to eliminate the RSCE. Until such breakthrough is made, process yields can be significantly increased by making delay lines 10 with transistors having channel lengths in the RSCE range. The delay line 10, in accordance with the present invention, may be used in a wide variety of applications. For example, the delay line 10 may be used in the phase detector of a phase locked loop (PLL), or in a delta sigma analog-to-digital converter.

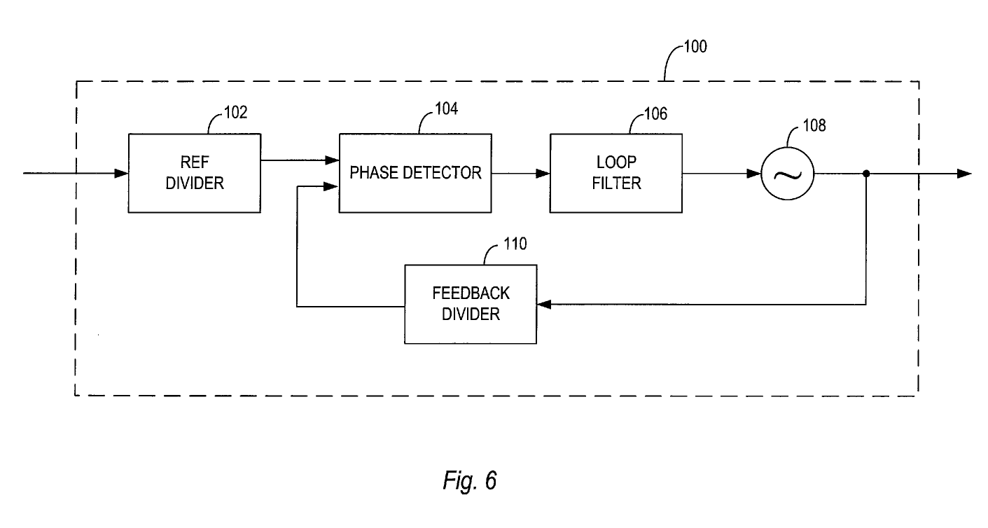

FIG. 6 illustrates an exemplary PLL 100 with a delay line 10 according to the present invention. The PLL 100 includes an optional reference divider 102, a phase detector 104, a loop filter 106, a voltage-controlled oscillator (VCO) 108, and a feedback divider 110. The optional reference divider 102 may take an incoming reference signal and divide it down to an appropriate frequency, if necessary. Phase detector 104 compares the phase of the reference signal and the output of the feedback divider 110 to generate a phase correction signal that is proportional to the phase error. The phase correction signal is filtered by loop filter 106 and input to the VCO 108. The VCO 108 generates an output signal based on the phase correction signal.

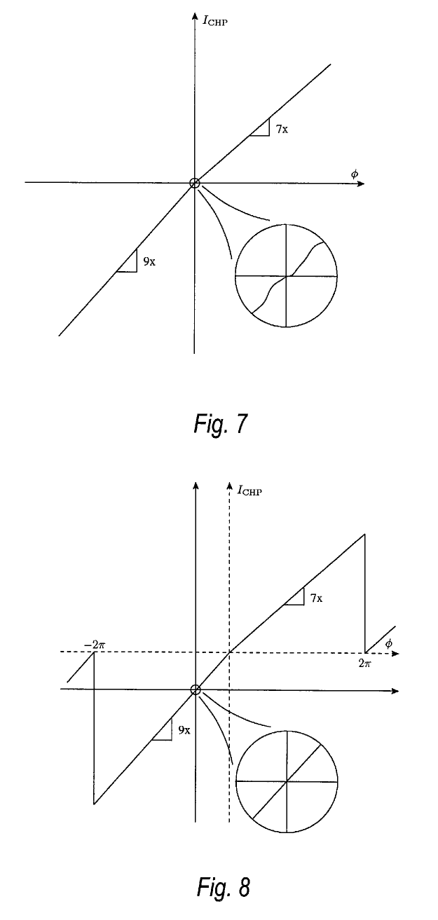

FIG. 7 illustrates an exemplary detector transfer function for the phase detector 104. The detector transfer function is, in its simplest form, a linear function that crosses the origin in the phase correction signal-phase error space. In a typical implementation of the phase detector 104, the transfer function is not linear and may have significant distortion in the area close to the origin known as the dead zone. To avoid the distortion near the origin of the coordinate system, a delay line 10 as shown in FIG. 1 can be used to implement an asymmetric delay in the phase detector 104. The asymmetric delay shifts the coordinate system as shown in FIG. 8 so that the transfer function close to the origin is linear. The delay line 10 should meet strict manufacturing requirements to be useful in large volume integrated circuits. A too large a delay results in excessive noise generated by the charge pump current source. A too small delay results in downconverted quantization noise close to the carrier for delta-sigma fractional-n PLLs due to the non-linearities of the phase detector 104.

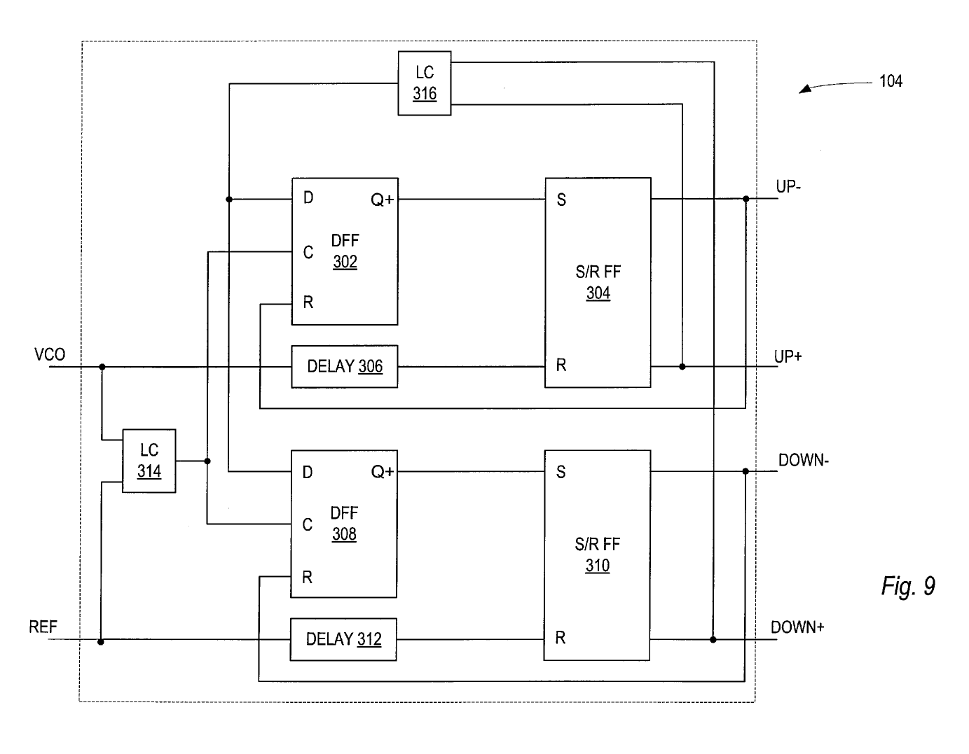

FIG. 9 illustrates an exemplary phase detector 104 incorporating a delay line. Phase detectors 104 comprises a first D flip-flop 302, first S/R flip-flop 304, first delay line 306, second D flip-flop 308, second S/R flip-flop 310, second delay line 312, first logic gate 314, and a second logic gate 316. The VCO input connects to the clock input of the first D flip-flop 302 through the first logic circuit 314, and to the reset input of the first S/R flip-flop 304 through the first delay line 306. Output Q+ of the first D flip-flop 302 is connected to the set input of the first S/R flip-flop 304. The reference input connects to the clock input of the second D flip-flop 308 through the first logic gate 314 and to the reset input of the second S/R flip-flop 310 through the second delay line 312. Output Q+ of the second D flip-flop 308 connects to the set input of the second S/R flip-flop 310. The UP+ and DOWN+ outputs of the first S/R flip-flop 304 and second S/R flip-flop 310 respectively connect through the second logic circuit 316 to the D input of the first and second D flip-flops 302, 308. The UP− output of the first S/R flip-flop connects to the reset input of the first D flip-flop 302 and the DOWN− output of the second S/R flip-flop 310 connects to the reset input of the second D flip-flop 308. The UP−,UP+,DOWN−, and DOWN+ outputs are applied to a charge pump (not shown) to generate the correction signal as is known in the art. The operation of the phase detector 104 is known and therefore not described herein except to note that the delay lines 304 and 306 are used to adjust the operating point of the phase detector 104 to shift the coordinate system away from the dead zone.

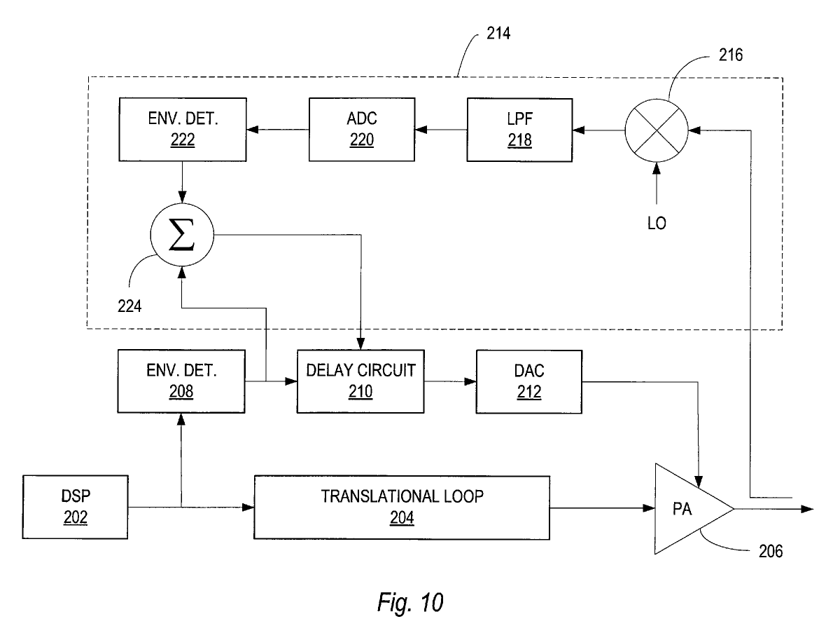

FIG. 10 is a schematic block diagram of an amplifier circuit 200 incorporating a delay line. The amplifier circuit 200 includes a digital signal processor 202, translational loop 204, power amplifier 206, envelope detector 208, delay circuit 210, and digital-to-analog converter (DAC) 212. The digital signal processor 202 produces a modulated baseband signal from an in-phase signal (I) and a quadrature signal (Q). The baseband signal is applied to the translational loop 204. The translational loop 204 extracts the phase information from the baseband signal produced by the digital signal processor 202 and up-converts the baseband signal to an RF phase signal that is applied to the input of the power amplifier 206. Envelope detector 208 detects the envelope of the modulated baseband signal and generates an envelope signal. The envelope signal is used to modulate the power supply of the power amplifier 206. A delay circuit 210 is provided to match the delay of the envelope signal to the phase signal applied to the power amplifier 206. The delay circuit 210 may, for example, comprise the circuit shown in FIGS. 1 and 2.

The amount of the delay added by the delay circuit 210 is determined by a delay calibration circuit 214. The delay calibration circuit 214 comprises a mixer 216, low pass filter 218, analog-to-digital converter 220, an envelope detector 222, and summing node 224. The output signal from the power amplifier 206 is down-converted to baseband frequency by mixer 216 and filtered by low-pass filter 218 to produce a feedback signal. Analog-to-digital converter 220 converts the feedback signal into a digital signal that is applied to the envelope detector 222. The envelope detector 222 generates a feedback envelope signal that is applied to the summing node 224. The summing node 224 produces a delay error signal based on a difference in the feedback envelope signal produced by the envelope detector 222 and the envelope signal produced by the envelope detector 208. The delay error signal is applied to the delay circuit 210 to vary the delay in the envelope signal path.

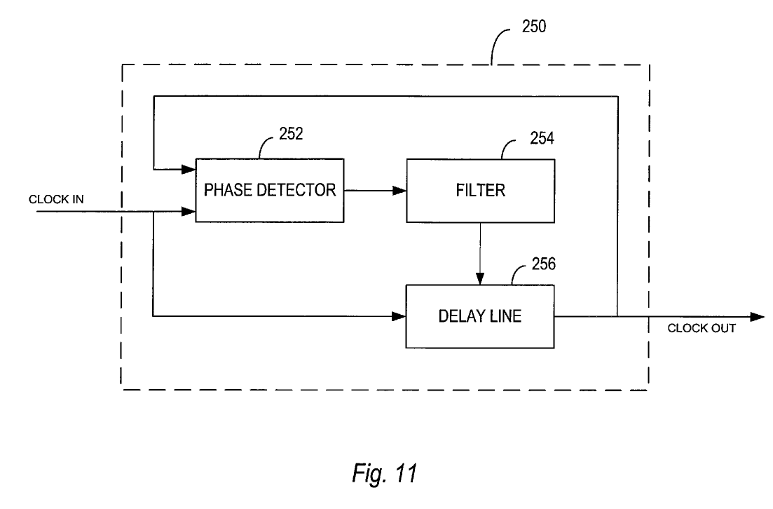

FIG. 11 illustrates an exemplary delay locked loop. The delay lock loop 250 includes a phase detector 252, filter 254, and delay line 256. The phase detector 252 compares the phase of the output clock to an input clock and generates an error signal. The error signal is filtered by filter 254 to generate a control signal that is applied to the delay line 256. The control signal sets the variable delay of the delay line 256. The delay line 256 delays the clock output to maintain a fixed phase relationship with the clock input.

The delay line can also be used in a digital-to-analog or analog-to digital converter, delta-sigma quantizer, delta-sigma modulator and numerous other circuits, where precise delay is required.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

What is claimed is:

1. A method for reducing delay spread in a delay line, said method comprising:
forming said delay line comprising a plurality of delay elements, each delay element comprising one or more transistors that exhibit a reverse short channel effect (RSCE) at channel lengths within an RSCE range; and
configuring said transistors in said delay elements to have channel lengths in said RSCE range.

2. The method of claim 1 wherein said delay elements comprise inverters.

3. The method of claim 2 wherein each inverter comprises a pair of complementary transistors connected in series and configured to be alternately enabled.

4. The method of claim 1 wherein said transistors comprise CMOS transistors.

5. The method of claim 1 wherein said transistors are configured to have a nominal channel length near a midpoint of the RSCE range.

6. A delay line comprising:
a plurality of transistors that exhibit a reverse short channel effect at channel lengths within an RSCE range; and
said transistors configured to have a channel length in said RSCE range.

7. The delay line of claim 6 wherein said transistors are connected to form an inverter chain.

8. The delay line of claim 7 wherein each inverter comprises a pair of complementary transistors connected in series and configured to be alternatively enabled.

9. The delay line of claim 6 wherein said transistors comprise CMOS transistors.

10. The delay line of claim 6 wherein said transistors are configured to have a nominal channel length near a midpoint of said RSCE range.

11. A circuit comprising:
a delay line comprising a plurality of delay elements connected in series, each delay element comprising one or more transistors that exhibit a reverse short channel effect at channel lengths within a certain range; and
wherein said transistors in said delay element are configured to have channel lengths in said certain range.

12. The circuit of claim 11 wherein said delay elements comprise inverters.

13. The circuit of claim 12 wherein each inverter comprises a pair of complementary transistors connected in series and configured to be alternatively enabled.

14. The circuit of claim 11 wherein said transistors comprise CMOS transistors.

15. The circuit of claim 11 wherein said transistors are configured to have a nominal channel length near a midpoint of said certain range.

16. The circuit of claim 11 configured as a phase-locked loop.

17. The circuit of claim 11 configured as an analog-to-digital or digital-to-analog converter.

18. The circuit of claim 11 configured as a delay locked loop.

19. The circuit of claim 11 configured as a switched or digital power amplifier.
